(19) United States
(12) Patent Application Publication
(10) Pub. No.: US 2013/0129983 A1
(43) Pub. Date: May 23, 2013

(54) SILICON CARBIDE STABILIZING OF SOLID DIAMOND AND STABILIZED MOLDED AND FORMED DIAMOND STRUCTURES

(71) Applicant: Victor B. Kley, Berkeley, CA (US)

(72) Inventor: Victor B. Kley, Berkeley, CA (US)

(73) Assignee: Metadigm LLC, Berkeley, CA (US)

(21) Appl. No.: 13/474,637

(22) Filed: May 17, 2012

Related U.S. Application Data
(63) Continuation of application No. 11/949,742, filed on Dec. 3, 2007.
Application No. 11/949,742 is a continuation of application No. 11/079,019, filed on Mar. 11, 2005, now abandoned.
(60) Provisional application No. 60/554,194, filed on Mar. 16, 2004.

(51) Int. Cl. C23C 16/32

(52) U.S. Cl. CPC C23C 16/325
USPC 428/164; 428/161; 427/249.16; 428/408

(57) ABSTRACT

A technique allows diamonds, whether synthetic or naturally occurring, and regardless of shape, to resist high temperatures in an oxidizing environment. This is accomplished by coating the diamond with silicon carbide (SiC). The resulting product may be referred to as SiC-stabilized diamond. A further benefit with respect to diamond jewelry is that by applying SiC to the diamond jewel, a unique pattern is made by small variations in the film thickness. These variations appear under UV and X-ray examination, and along with a unique and invariant weight, provide a unique signature to the jewel.

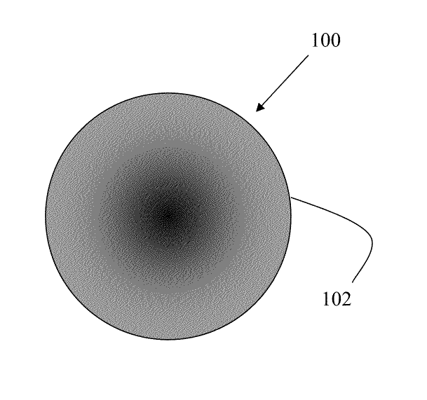

### CROSS-REFERENCES TO RELATED APPLICATIONS

This application is a continuation of U.S. patent application Ser. No. 11,949,742, filed Dec. 3, 2007, entitled “Silicon Carbide Stabilizing of Solid Diamond and Stabilized Molded and Formed Diamond Structures,” which is a continuation of U.S. patent application Ser. No. 11/079,019 filed Mar. 11, 2005, entitled “Silicon Carbide Stabilizing of Solid Diamond and Stabilized Molded and Formed Diamond Structures,” which claims the benefit of U.S. Provisional Application No. 60/554,194 filed Mar. 16, 2004, entitled “Silicon Carbide Stabilizing of Solid Diamond and Stabilized Molded and Formed Diamond Structures,” which disclosure (including the document attached thereto and characterized as “Novel Low-Temperature CVD Process for Silicon Carbide MEMS, C. R. Stoldt, C. Carraro, W. R. Ashurst, M. C. Fritz, D. Gao, and R. Maboudian, Department of Chemical Engineering, University of California, Berkeley, Calif. 94720 U.S.A.”) is incorporated herein by reference for all purposes.

### BACKGROUND AND SUMMARY OF THE INVENTION

The following U.S. patents are incorporated by reference: U.S. Pat. Nos. 6,144,028, 6,252,226, 6,337,479, 6,339,217.

The present invention relates generally to diamonds, and more specifically to techniques for increasing the longevity of diamonds. Yes, it's true, diamonds are not forever.

Diamonds, whether synthetic or naturally occurring, and regardless of shape, suffer from the inability to resist high temperatures in an oxidizing environment. They burn like what they are, very expensive charcoal. In fact diamonds exposed to air at room temperature lose a small but measurable amount of carbon over time.

The present invention eliminates this problem, and thus improves the longevity and value of diamond articles such as natural and synthetic diamond jewelry, certain diamond industrial applications, and the emerging area of diamond as a structural material in building useful devices and machines. In short, this is accomplished by coating the diamond with silicon carbide (SiC). The resulting product may be referred to as SiC-stabilized diamond.

A further benefit with respect to diamond jewelry is that by applying SiC to the diamond jewel, a unique pattern is made by small variations in the film thickness. These variations appear under UV and X-ray examination, and along with a unique and invariant weight, provide a unique signature to the jewel.

In another aspect of the invention, the SiC coating (which may be doped to be conductive or left in its intrinsic form as an insulator) may be achieved by direct coating of diamond, or by the use of a thin layer of silicon to act as an adhesion layer between the diamond and SiC, or by use of a thicker layer of silicon or other material to permit thicker structures of SiC and diamond to be bonded together. This coating is useful in storing or handling and protecting diamond shapes such as spheres used for ball bearings and the like.

It is noted that for those embodiments where the diamond is formed on a sacrificial substrate (e.g., a sphere on which a diamond shell is grown), which substrate is later wholly or partially removed, the protective layer can also be wholly or partially removed.

Further improvements, resistance to oxygen penetration of the SiC layer along with specific optical and identification functions by any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide. By suitably varying the materials and thickness of successive layers we can construct an optically specific coating that can substantially identify any given transparent coated structure like a diamond jewel with a unique signature by scattered light or by coherent light or both and/or mass.

A further understanding of the nature and advantages of the present invention may be realized by reference to the remaining portions of the specification and the drawings.

### BRIEF DESCRIPTION OF THE DRAWING

The drawing shows a specific embodiment of silicon carbide seeding on a diamond by a light coat of silicon (10 to 15 nm) followed by a silicon carbide or quick carbon plasma.

### DESCRIPTION OF SPECIFIC EMBODIMENTS

The drawing shows a specific embodiment of silicon carbide (SiC) seeding on a diamond by a light coat of silicon (10 to 15 nm) followed by a silicon carbide or quick carbon plasma. The first silicon coat forms carbides with the diamond; the second grows SiC. In the preferred embodiment a diamond such as jewel 100 is implanted with a seed layer of silicon, forming silicon carbide sites 102. A silicon carbide coating is then applied by CVD growth of the silicon carbide.

The technique is well known in the art, and can follow the teachings of the reference Novel Low-Temperature CVD Process for Silicon Carbide MEMS, C. R. Stoldt, C. Carraro, W. R. Ashurst, M. C. Fritz, D. Gao, and R. Maboudian, Department of Chemical Engineering, University of California, Berkeley, Calif. 94720 U.S.A., which uses 1,3-disilabutane, including such latter coating at low temperatures as described. Alternatively, a plasma arc is made with silicon carbide and allowed to condense on the seeded surface.

Thus it can be seen that various embodiments provide methods and articles of manufacture that may include the coating of CVD, PECVD, synthetic solid, or natural solid diamond with any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide.

While the above is a complete description of specific embodiments of the invention, the above description should not be taken as limiting the scope of the invention as defined by the claims.

What is claimed is:

1. A method of treating a diamond comprising depositing a layer of silicon carbide on the diamond.

2. The method of claim 1 wherein any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide are used for any reason.

3. The method of claim 1 wherein the layer or layers vary in thickness between 10 nm and 100 microns.

4. The method of claim 1, and further comprising depositing a layer of silicon, on which the silicon carbide layer is deposited.

5. The method of claim 4 wherein any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide are used for any reason.

6. The method of claim 4 wherein the layer or layers vary in thickness between 10 nm and 100 microns.

7. The method of claim 1 wherein the diamond is one of a CVD grown diamond, a PECVD grown diamond, a synthetic solid diamond, or a natural solid diamond.

8. The method of claim 1 wherein the silicon carbide layer is on the order of 1 micron in thickness.

9. The method of claim 1 wherein the silicon carbide layer is between 10 nanometers and 200 nanometers in thickness.

10. The method of claim 1 wherein the silicon carbide layer is doped to have a desired conductivity.

11. The method of claim 1 in which a unique combination of layers, thickness variations and mass provide a signature which can not be duplicated and may be recorded and used to identify the object.

12. An article of manufacture comprising:
a diamond shape having a surface; and
a silicon carbide layer conforming to at least a portion of said surface of said diamond shape.

13. The article of claim 12 wherein the layer or layers vary in thickness between 10 nm and 100 microns.

14. The method of claim 12 wherein any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide are used for any reason.

15. The article of claim 12, and further comprising a silicon layer interposed between at least a portion of said silicon carbide layer and said surface of said diamond shape.

16. The method of claim 15 wherein any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide are used for any reason.

17. The method of claim 15 wherein any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide are used for any reason.

18. The article of claim 15 wherein the layer or layers vary in thickness between 10 nm and 100 microns.

19. The article of claim 15 in which a unique combination of layers, thickness variations and mass provide a signature which can not be duplicated and may be recorded and used to identify the object.

20. A method that includes the coating of CVD, PECVD, synthetic solid, or natural solid diamond with any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide.

21. An article of manufacture that includes the coating of CVD, PECVD, synthetic solid, or natural solid diamond with any or all of silicon carbide, silicon, silicon fluoride, magnesium fluoride, silicon nitride, titanium, titanium dioxide, carbide, titanium nitride, tantalum, tantalum carbide, tantalum nitride, molybdenum, molybdenum carbide, molybdenum nitride, tungsten, tungsten carbide, tungsten nitride, boron carbide, boron nitride, chromium, chromium carbide, chromium nitride, chromium oxide, aluminum oxide.
